(19) United States
(12) Patent Application Publication
(10) Pub. No.: US 2006/0170459 A1
(43) Pub. Date: Aug. 3, 2006

(54) Multiplexer and methods thereof

(75) Inventors: Jong-Shin Shin, Seoul (KR); Ji-Young Kim, Osan-si (KR); Myoung-Bo Kwak, Seoul (KR); Il-Won Seo, Yongin-si (KR); Chi-Won Kim, Hwaseong-si (KR); Hyun-Goo Kim, Seoul (KR); Jae-Hyun Park, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/340,458

(22) Filed: Jan. 27, 2006

(30) Foreign Application Priority Data
Jan. 31, 2005 (KR) 10-2005-0008750

(51) Int. Cl. H03K 19/094

(52) U.S. Cl. 326/113

(57) ABSTRACT

A multiplexer and methods thereof. In an example, the multiplexer may receive a first periodic signal with a first active duration and a second periodic signal with a second active duration, the first and second active durations not overlapping. The multiplexer may transition statuses of first and second transmission gates based on the first and second periodic signals, respectively, such that each of the first and second transmission gates are set to the same status during at least one time period (e.g., between the first and second active durations where both the first and second periodic signals are inactive). In a further example, the example multiplexer may include first and second transmission gates receiving first and second input signals which may be controlled by the first and second control signals.

### PRIORITY STATEMENT

This application claims the benefit of Korean Patent Application No. 10-2005-0008750, filed on Jan. 31, 2005, in the Korean Intellectual Property Office, the disclosure of which is incorporated herein in its entirety by reference.

### BACKGROUND OF THE INVENTION

1. Field of the Invention

Example embodiments of the present invention are related generally to a multiplexer and methods thereof, and more particularly to a multiplexer and methods of controlling a multiplexer.

2. Description of the Related Art

In a conventional spread spectrum clock generator (SSCG) and/or a conventional delay lock loop (DLL), a phase interpolator and/or a phase blender may be used for generating a plurality of clock signals having uniform fine phase differences. The phase blender may employ a digital inverter, thereby having a simpler structure as compared to the phase interpolator and may be used with signals having higher swing widths.

The phase blender may generate a plurality of clock signals having uniform fine phase differences. One of the plurality of clock signals may be selected with a multiplexer. Transferring the selected clock signal to an output port of the multiplexer without excessive jitter may be an important design characteristic of the phase blender.

For example, if two clock signals input to a 2:1 multiplexer have different phases, the phases of the input clock signals and a control signal for controlling the multiplexer (e.g., for determining which of the two input clock signals may be selected) may each be different. Thereby, an activation time point of the control signal may not be aligned with middle points of one or more of the input clock signals. Accordingly, as a ratio of the rise and fall times (e.g., swing widths) of the input clock signals to the period of the input clock signal increases, a probability that the input clock signals and the control signal may be simultaneously switched may increase. If the input clock signal and the control signal are simultaneously switched, a phase jump may be generated such that a phase variation of an output clock signal may be higher than the phase difference between the two input clock signals. Phase jumps may cause additional jitter in the output clock signal.

FIG. 1 is a circuit diagram of a conventional multiplexer 100. FIG. 2 is a timing diagram of control signals used in the conventional multiplexer 100 of FIG. 1.

Referring to FIGS. 1 and 2, the multiplexer 100 may include inverters 11, 12, 13 and 16 and transmission gates 14 and 15. A second control signal CON_B may be an inverted version of a first control signal CON_A. Accordingly, a first input clock signal φA and a second input clock signal φB may not be concurrently (e.g., simultaneously) output to a common output port NC (e.g., because the first and second control signals CON_A and CON_B may be set to different logic levels). One of the first and second input clock signals φA and φB may be selected by the multiplexer 100 and output to the common output port NC.

FIG. 3 illustrates a phase difference TPD between the first input clock signal φA and the second input clock signal φB received by the multiplexer 100 of FIG. 1.

Referring to FIG. 3, outside of a region 31, the first input clock signal φA and the second input clock signal φB may be set to a first logic level (e.g., a higher logic level). Within the region 31, the first input clock signal φA and the second input clock signal φB may be set to different voltages in a period during a falling time (e.g., a transition from the first logic level (e.g., a higher logic level) to a second logic level (e.g., a lower logic level)), thereby generating the phase difference TPD between first input clock signal φA and second input clock signal φB. It is understood that a similar phase difference may also occur during a rising edge transition (e.g., a transition from the second logic level (e.g., a lower logic level) to the first logic level (e.g., a higher logic level)).

Referring to FIG. 3, if the first input clock signal φA and the second input clock signal φB are set to the same logic level, the output clock signal OUT may not vary based on a variance in the logic levels of the first control signal CON_A and the second control signal CON_B. However, if the logic levels of the first control signal CON_A and the second control signal CON_B vary and the first input clock signal φA and the second input clock signal φB vary (e.g., as illustrated in the region 31 of FIG. 3), a resistance and capacitance of transmission gates (e.g., transmission gates 14 and 15 of FIG. 1) may vary during a switching operation. The output clock signal OUT may thereby not be linear, which may cause distortion. The phase of the output clock signal OUT may thereby not be softly switched (e.g., switched without distortion) from the phase of the first input clock signal φA to the phase of the second input clock signal φB. Accordingly, a phase jump may be generated in the output clock signal OUT such that the phase variation of the output clock signal OUT may be greater than the phase difference TPD between the two input clock signals φA and φB, which may cause additional jitter of the output clock signal OUT.

### SUMMARY OF THE INVENTION

An example embodiment of the present invention is directed to a multiplexer, including a first transmission gate receiving a first input signal input at a first input port and transferring the received first input signal to a common output port in response to a first control signal and a second transmission gate receiving a second input signal input at a second input port and transferring the received second input signal to the common output port in response to a second control signal, the first and second control signals set to respective logic levels which do not overlap and including at least one period of time when the first and second control signals are set to the same logic level.

Another example embodiment of the present invention is directed to a method of controlling a multiplexer, including generating a first control signal with a first control period and a second control signal with a second control period and transitioning first and second transmission gates such that each of the first and second transmission gates are set to a first status based on the first and second control signals in at least one time period, the at least one time period positioned between active time periods of the first and second control signals.

Another example embodiment of the present invention is directed to a method of controlling a multiplexer, including inverting a first input signal and outputting a first inverted input signal, inverting a second input signal and outputting a second inverted input signal, transferring one of the inverted first input signal and the inverted second input signal to a common output port during a first time period, transferring each of the inverted first input signal and the inverted second input signal to the common output port in during a second time period and inverting a signal at the common output port and outputting the inverted common output port signal.

Another example embodiment of the present invention is directed to a method of controlling a multiplexer, including receiving a first periodic signal with a first active duration, receiving a second periodic signal with a second active duration, the first and second active durations not overlapping and transitioning statuses of first and second transmission gates based on the first and second periodic signals, respectively, such that each of the first and second transmission gates are set to the same status during at least one time period.

Another example embodiment of the present invention is directed to a multiplexer and method thereof which does not generate a phase jump in an output clock signal, even though logic levels of control signals may vary when input clock signals vary.

### BRIEF DESCRIPTION OF THE DRAWINGS

The accompanying drawings are included to provide a further understanding of example embodiments of the invention, and are incorporated in and constitute a part of this specification. The drawings illustrate example embodiments of the present invention and, together with the description, serve to explain principles of the present invention.

FIG. 1 is a circuit diagram of a conventional multiplexer.

FIG. 2 is a timing diagram of control signals used in the conventional multiplexer of FIG. 1.

FIG. 3 illustrates a phase difference between a first input clock signal and a second input clock signal received by the conventional multiplexer of FIG. 1.

FIG. 4 is a circuit diagram of a multiplexer according to an example embodiment of the present invention.

FIG. 5 is a timing diagram of control signals used in the multiplexer of FIG. 4 according to another example embodiment of the present invention.

FIG. 6 is a timing diagram of signals of input signals and control signals concurrently varying in the multiplexer of FIG. 4 according to another example embodiment of the present invention.

FIG. 7 illustrates simulation results of the conventional multiplexer of FIG. 1.

FIG. 8 illustrates simulation results of the multiplexer of FIG. 4 according to another example embodiment of the present invention

FIG. 9A illustrates the minimum jitter of an output signal when variations of input signals do not overlap with variations of control signals in both the conventional multiplexer of FIG. 1 and the multiplexer of FIG. 4.

FIG. 9B illustrates the minimum jitter of an output signal when variations of input signals overlap with variations of control signals in the conventional multiplexer of FIG. 1.

FIG. 9C illustrates the minimum jitter of an output signal when variations of input signals overlap with variations of control signals in the multiplexer of FIG. 4.

FIG. 10 is a block diagram illustrating a conventional circuit for generating signals having different phases and the same phase difference between respective signals using a phase blender.

FIG. 11 is a circuit diagram illustrating the conventional phase blender units.

FIG. 12 is a block diagram illustrating a circuit for generating signals having different phases with the same phase difference (e.g., between respective signals) according to another example embodiment of the present invention.

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

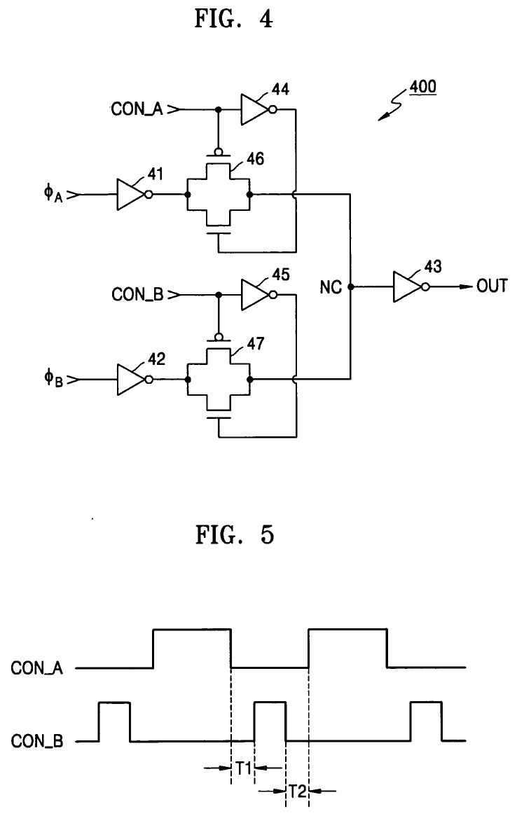

FIG. 4 is a circuit diagram of a multiplexer 400 according to an example embodiment of the present invention. FIG. 5 is a timing diagram of control signals used in the multiplexer 400 of FIG. 4 according to another example embodiment of the present invention.

In the example embodiment of FIG. 4, the multiplexer 400 may include a first inverter 41, a second inverter 42, a third inverter 43, a fourth inverter 44, a fifth inverter 45, a first transmission gate 46, and a second transmission gate 47. The first inverter 41 may invert a first input signal φA and may output a first inverted signal. The second inverter 42 may invert a second input signal φB and may output a second inverted signal. The fourth inverter 44 and the fifth inverter 45 may invert a first control signal CON_A and a second control signal CON_B, respectively, and may output third and fourth inverted signals, respectively.

In the example embodiment of FIG. 4, the first transmission gate 46 may transmit the first inverted signal output by the first inverter 41 to a common output port NC in response to the first control signal CON_A. The second transmission gate 47 may transmit the second inverted signal output by the second inverter 42 to the common output port NC in response to the second control signal CON_B. For example, the first transmission gate 46 may transmit the first inverted signal output the first inverter 41 to the common output port NC if the first control signal CON_A is set to a second logic level (e.g., a lower logic level). Likewise, in a further example, the second transmission gate 47 may transmit the second inverted signal output by the second inverter 42 to the common output port NC if the second control signal CON_B is set to the second logic level.

In the example embodiment of FIG. 4, the third inverter 43 may invert a signal of the common output port NC and may output an output signal OUT (e.g., an inverted version of a signal received from the common output port NC).

In the example embodiment of FIG. 5, the first control signal CON_A and the second control signal CON_B may be non-overlapping signals (e.g., as illustrated in FIG. 5) in that active portions (e.g., at the first logic level) may not be present in both the first and second control signals at the same times. In an example, the first transmission gate 46 may be turned on in response to the first control signal CON_A. The second transmission gate 47 may be turned off in response to the second control signal CON_B after a first period of time T1. The second transmission gate 47 may be turned on in response to the second control signal CON_B and the first transmission gate 46 may be turned off in response to the first control signal CON_A after a second period of time T2. Thereby, the first and second transmission gates 46 and 47 may each be turned on during the first and second periods of time T1 and T2.

In the example embodiment of FIG. 5, before the period T1, the first control signal CON_A may be set to the first logic level (e.g., a higher logic level) and the second control signal CON_B may be set to the second logic level (e.g., a lower logic level). The first transmission gate 46 may thereby be turned off and the second transmission gate 47 may be turned on. Accordingly, the second input signal φB may be output as the output signal OUT through the second inverter 42, the second transmission gate 47, the common output port NC, and the third inverter 43.

In the example embodiment of FIG. 5, between the periods T1 and T2, the first control signal CON_A may be set to the second logic level (e.g., a lower logic level) and the second control signal CON_B may be set to the first logic level (e.g., a higher logic level). The first transmission gate 46 may thereby be turned on and the second transmission gate 47 may be turned off. The first input signal φA may be output as the output signal OUT through the first inverter 41, the first transmission gate 46, the common output port NC, and the third inverter 43.

In the example embodiment of FIG. 5, within the periods T1 and/or T2, the first control signal CON_A may be set to the second logic level (e.g., a lower logic level) and the second control signal CON_B may be set to the second logic level (e.g., a lower logic level). Each of the first and second transmission gates 46 and 47 may thereby be turned on. In this example, within the periods of T1 and/or T2, the multiplexer 400 of FIG. 4 may operate as a phase blender (e.g., not as a multiplexer).

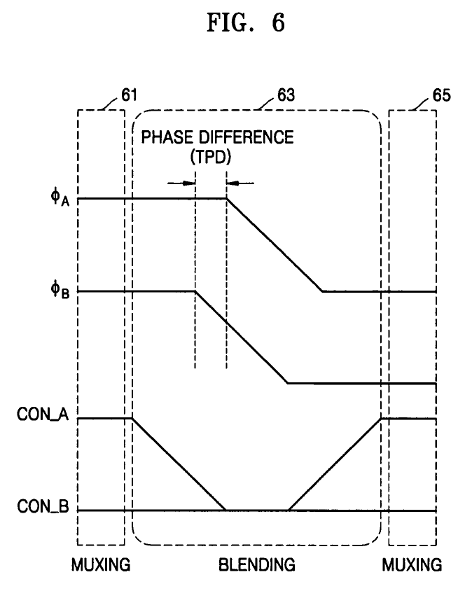

FIG. 6 is a timing diagram of signals of input signals φA and φB and control signals CON_A and CON_B concurrently varying in the multiplexer 400 of FIG. 4 according to another example embodiment of the present invention.

In the example embodiment of FIG. 6, if the voltages of the first input signal φA and the second input signal φB are set to the same logic level in a period 63, the output signal OUT may set to the same logic level as the first and second input signals φA and φB, although the input signals φA and φB may be “blended” (e.g., mixed such that an intermediate logic level is reached).

In the example embodiment of FIG. 6, if the voltages of the first input signal φA and the second input signal φB are different, the output signal OUT may be output at an average of the voltages of the first input signal φA and the second input signal φB.

In the example embodiment of FIG. 6, if the phases of the first input signal φA and the second input signal φB are blended in the period 63, a middle phase may be output, the middle phase being between the phases of the first input signal φA and the second input signal φB. Accordingly, the phase of the output signal OUT may be softly switched (e.g., switched without distortion) from the phase of the first input signal φA to the phase of the second input signal φB via the middle phase. Accordingly, a phase jump, which may cause additional jitter, may be reduced (e.g., avoided) in the output signal OUT.

In the example embodiment of FIG. 6, if both the first transmission gate 46 and the second transmission gate 47 are turned on, the period T1 and/or T2 may be longer than a sum of a transition time (e.g., the fall time and/or rise time of the first input signal φA and/or the second input signal φB) and the phase difference TPD between the first input signal φA and the second input signal φB and may be shorter than half the period of the input signal φA and/or φB.

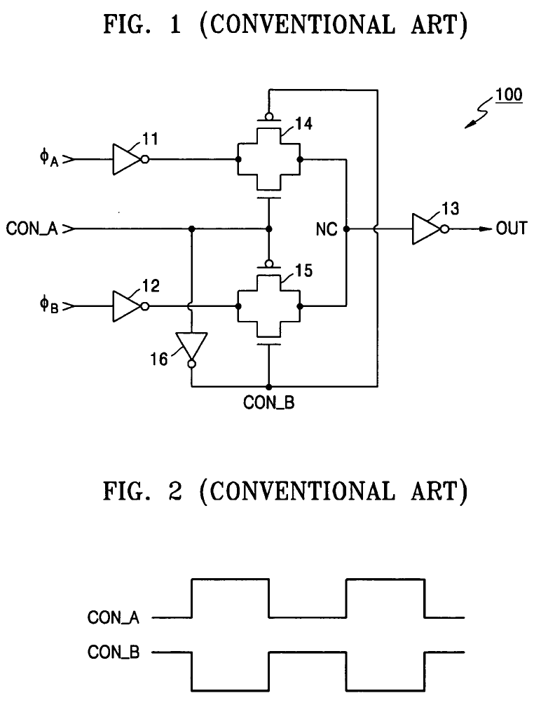

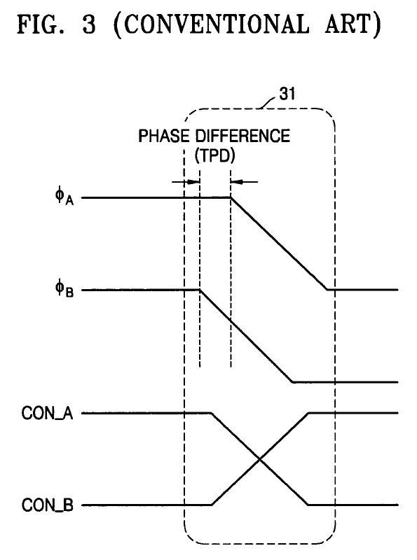

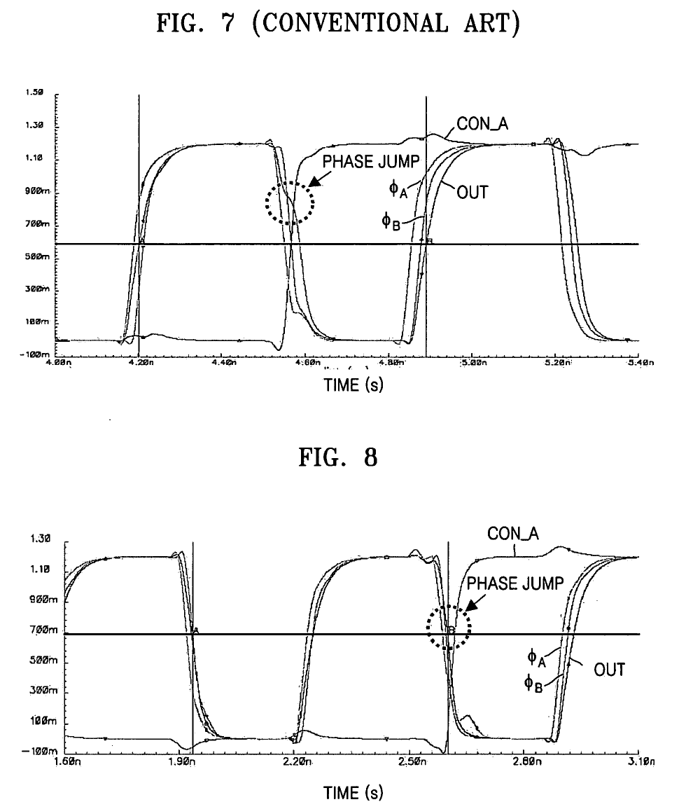

FIG. 7 illustrates simulation results of the conventional multiplexer 100 of FIG. 1. Referring to FIG. 7, a phase jump may be generated in the output signal OUT when the input signals φA and φB and the control signal CON_A each vary at the same time.

FIG. 8 illustrates simulation results of the multiplexer 400 of FIG. 4 according to another example embodiment of the present invention. In the example embodiment of FIG. 8, a phase jump may be reduced (e.g., avoided) during a concurrent variance of the input signals φA and φB and the control signal CON_A.

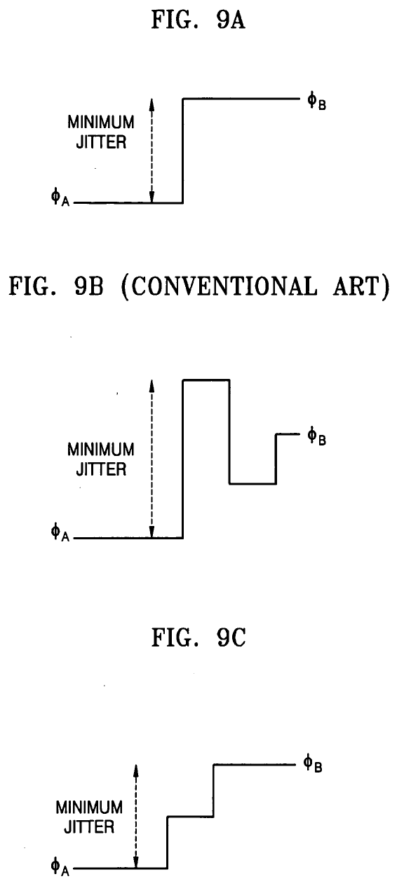

FIG. 9A illustrates the minimum jitter of the output signal OUT when variations of the input signals φA and φB do not overlap with variations of the control signals CON_A and CON_B in both the conventional multiplexer 100 of FIG. 1 and the multiplexer 400 of FIG. 4.

FIG. 9B illustrates the minimum jitter of the output signal OUT when variations of the input signals φA and φB overlap with variations of the control signals CON_A and CON_B in the conventional multiplexer 100 of FIG. 1.

FIG. 9C illustrates the minimum jitter of the output signal OUT when variations of the input signals φA and φB overlap with variations of the control signals CON_A and CON_B in the multiplexer 400 of FIG. 4.

In FIG. 9B and the example embodiments of FIGS. 9A and 9C, φA may denote the phase of the first input signal and φB may denote the phase of the second input signal.

In the example embodiment of FIG. 9A, if variations of the input signals φA and φB do not overlap with variations of the control signals CON_A and CON_B in the conventional multiplexer 100 of FIG. 1 and/or the multiplexer 400 of FIG. 4, the minimum jitter of the output signal OUT may be φA-φB.

Referring to FIG. 9B, if variations of the input signals φA and φB overlap with variations of the control signals CON_A and CON_B in the conventional multiplexer 100 of FIG. 1, a phase jump (e.g., additional jitter) may be generated in the output signal OUT, and the minimum jitter may increase to a value greater than or equal to φA-φB.

In the example embodiment of FIG. 9C, if variations of the input signals φA and φB overlap with variations of the control signals CON_A and CON_B in the multiplexer 400 of FIG. 4, a phase jump may be reduced (e.g., avoided) by phase blending, and the minimum jitter may thereby be φA-φB (e.g., equivalent to the minimum jitter of FIG. 9A).

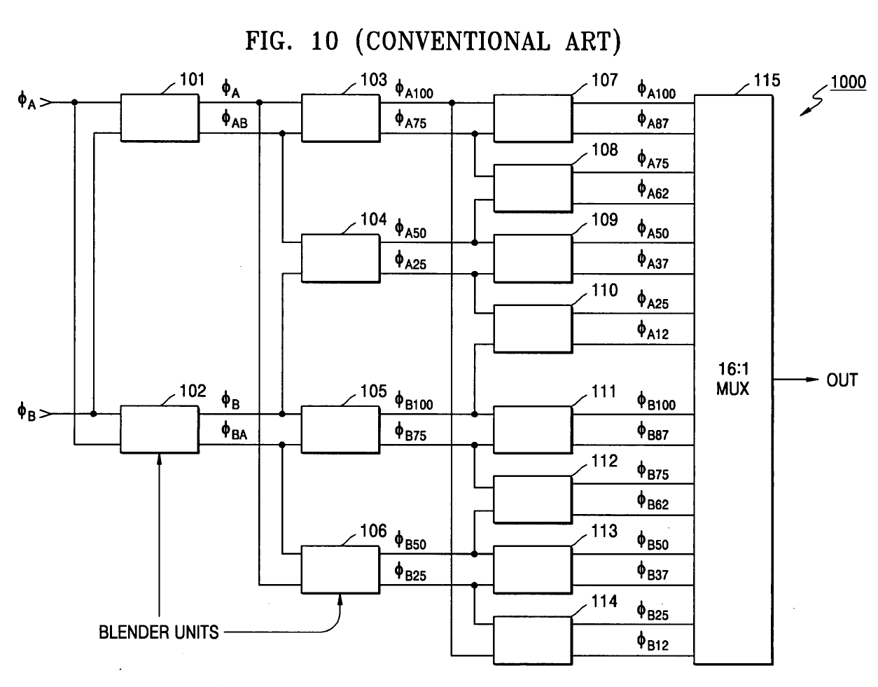

FIG. 10 is a block diagram illustrating a conventional circuit 1000 for generating signals φA100-φA12 and φB100-φB12 having different phases and the same phase difference between respective signals using a phase blender. Referring to FIG. 10, the conventional circuit 1000 may include phase blender units 101 through 114 and a 16:1 multiplexer 115.

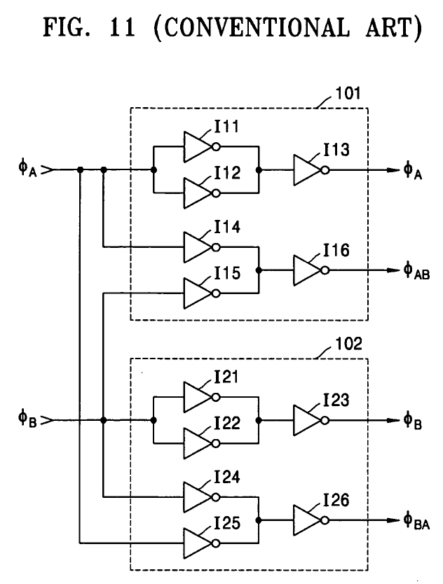

FIG. 11 is a circuit diagram illustrating the first and second phase blender units 101 and 102 of FIG. 10.

In the example embodiment of FIG. 11, the phase blender unit 101 may include portions I11 through I13 for generating an output signal φA having the same phase as an input signal φA and portions I14 through I16 for generating an output signal φAB having an intermediate phase (e.g., a phase between the phases of the input signal φA and an input signal φB). The phase blender unit 102 may include portions 121 through 123 for generating an output signal φB having the same phase as the input signal φB, and portions 124 through I26 for generating an output signal φBA having a middle phase between the phases of the input signal φB and the input signal φA.

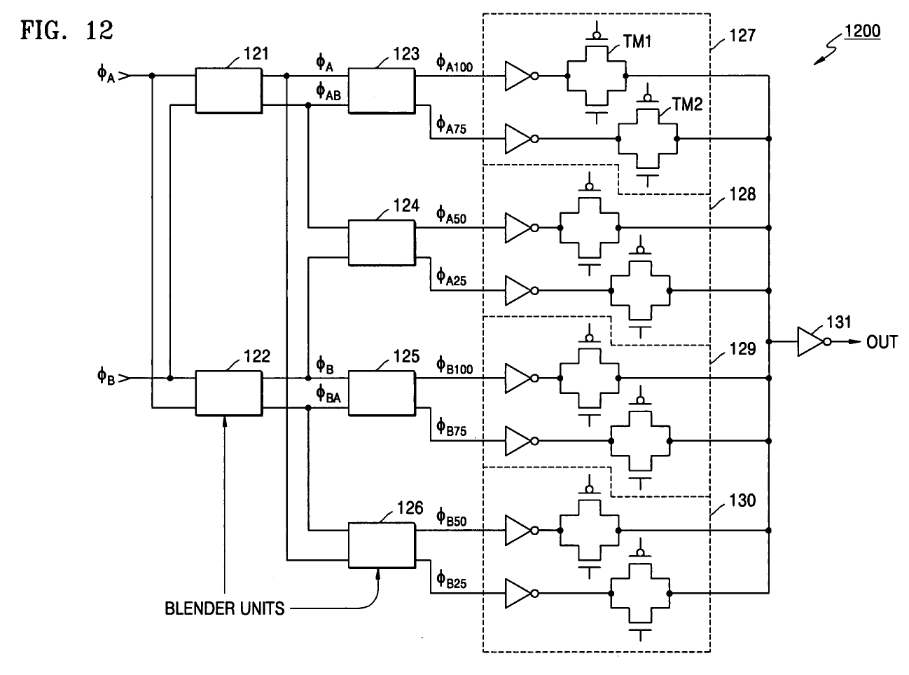

FIG. 12 is a block diagram illustrating a circuit 1200 for generating signals having different phases with the same phase difference (e.g., between respective signals) according to another example embodiment of the present invention. In the example embodiment of FIG. 12, the circuit 1200 may include phase blender units 121 through 126, 2:1 multiplexers 127 through 130, and an inverter 131 connected to a common output port MC of the multiplexers 127 through 130. In an example, each of the multiplexers 127 through 130 may be representative of the multiplexer 400 of FIG. 4.

In an example, referring to FIG. 12, the transmission gate TM1 may be turned on and the transmission gate TM2 may be turned off such that the multiplexer 127 may output a signal having the same phase as the output signal φA100 of the phase blender unit 123 to the common output port MC.

In another example, referring to FIG. 12, each of the transmission gates TM1 and TM2 may be turned on such that the multiplexer 127 may output a signal having an intermediate phase (e.g., a phase between the phases of the output signal φA100 and the output signal φA75 of the phase blender unit 123) to the common output port MC. In a further example, the control signals of the transmission gates TM1 and TM2 may be adjusted so as to control a functionality of the multiplexer 127.

In another example embodiment of the present invention, the circuit 1200 of FIG. 12 may be structurally less complex than the conventional circuit 1000 of FIG. 10, and the output signal OUT may further be softly switched without incurring a phase jump.

Example embodiments of the present invention being thus described, it will be obvious that the same may be varied in many ways. For example, while the above-described example embodiments of the present invention are directed generally to 2:1 and 16:1 multiplexers, it is understood that multiplexers according to other example embodiments of the present invention may be scaled to include any number of inputs. Further, while time periods T1 and T2 may both be shown as illustrated between the active durations of the control signals CON_A and CON_B, it is understood that other example embodiments of the present invention may include only one of the time periods T1 and/or T2, while still reducing (e.g., avoiding) at least some degree of distortion via a reduced (e.g. avoided) phase jump.

Further, while the above-described example embodiments include references to the first and second voltage and/or logic levels, in one example the first logic level may refer to a higher logic level and the second logic level may refer to a lower logic level. Alternatively, in another example, the first logic level may refer to a lower logic level and the second logic level may refer to a higher logic level.

Such variations are not to be regarded as departure from the spirit and scope of example embodiments of the present invention, and all such modifications as would be obvious to one skilled in the art are intended to be included within the scope of the following claims.

What is claimed is:

1. A multiplexer, comprising:
a first transmission gate receiving a first input signal input at a first input port and transferring the received first input signal to a common output port in response to a first control signal; and
a second transmission gate receiving a second input signal input at a second input port and transferring the received second input signal to the common output port in response to a second control signal, the first and second control signals set to respective logic levels which do not overlap and including at least one period of time when the first and second control signals are set to the same logic level.

2. The multiplexer of claim 1, wherein the second control signal is set to a first logic level if the first control signal is set to a second logic level.

3. The multiplexer of claim 1, wherein
the first transmission gate is turned on in response to the first control signal and the second transmission gate is turned off in response to the second control signal after a first period of time, and
the second transmission gate is turned on in response to the second control signal and the first transmission gate is turned off in response to the first control signal after a second period of time,
each of the first and second transmission gates being turned on during at least one of the first and second periods of time.

4. The multiplexer of claim 3, wherein at least one of the first and second periods of time is longer than a sum of a transition time of one of the first and second input signals and a phase difference between the first input signal and the second input signal and shorter than half the period of the first and second input signals.

5. The multiplexer of claim 1, further comprising:
a first inverter connected to the first input port, the first inverter inverting the first input signal and outputting a first inverted input signal to a first input port;
a second inverter connected to the second input port, the second inverter inverting the second input signal and outputting a second inverted input signal to a second input port; and
a third inverter including a third input port connected to the common output port, the third inverter inverting a common output port signal received from the common output port and outputting an inverted common output port signal.

6. A method of controlling a multiplexer, comprising:
generating a first control signal with a first control period and a second control signal with a second control period; and
transitioning first and second transmission gates such that each of the first and second transmission gates are set to a first status based on the first and second control signals in at least one time period, the at least one time period positioned between active time periods of the first and second control signals.

7. The method of claim 6, wherein the transitioning includes:
transitioning a first transmission gate to a second status and transitioning a second transmission gate to the first status;
transitioning the first transmission gate to the first status for an active portion of the first control period;
transitioning the second transmission gate to the second status after a first time period, the first time period shorter than the first control period;
transitioning the second transmission gate to the second status for an active portion of the second control period, the second control period shorter than the first control period;
transitioning the second transmission gate to the first status after the second control period; and
transitioning the first transmission gate to the first status after a second period of time.

8. The method of claim 7, wherein the first status is on and the second status is off.

9. The method of claim 7, wherein at least one of the first and second time periods is longer than a sum of a transition time of the first and second control signals and a phase difference between the first and second control signals and is shorter than half of at least one of the first and second control periods.

10. The method of claim 9, wherein the transition time is one of a falling time and a rising time.

11. A method of controlling a multiplexer, comprising:
inverting a first input signal and outputting a first inverted input signal;
inverting a second input signal and outputting a second inverted input signal;
transferring one of the inverted first input signal and the inverted second input signal to a common output port during a first time period;
transferring each of the inverted first input signal and the inverted second input signal to the common output port in during a second time period; and
inverting a signal at the common output port and outputting the inverted common output port signal.

12. A method of controlling a multiplexer, comprising:
receiving a first periodic signal with a first active duration;
receiving a second periodic signal with a second active duration, the first and second active durations not overlapping; and
transitioning statuses of first and second transmission gates based on the first and second periodic signals, respectively, such that each of the first and second transmission gates are set to the same status during at least one time period.

13. The method of claim 12, wherein the at least one time period includes a first period of time directly after the first active duration and a second period of time directly before a next first active duration.

14. The method of claim 12, wherein the first active duration is longer than the second active duration.

15. A multiplexer performing the method of claim 6.

16. A multiplexer performing the method of claim 11.

17. A multiplexer performing the method of claim 12.
